(19) United States
(12) Patent Application Publication
(10) Pub. No.: US 2024/0178301 A1
(43) Pub. Date: May 30, 2024

(54) HEMT TRANSISTOR OF THE NORMALLY OFF TYPE INCLUDING A TRENCH CONTAINING A GATE REGION AND FORMING AT LEAST ONE STEP, AND CORRESPONDING MANUFACTURING METHOD

(71) Applicant: STMICROELECTRONICS S.r.l., Agrate Brianza (IT)

(72) Inventors: Ferdinando IUCOLANO, Gravina di Catania (IT); Alfonso PATTI, Tremestieri Etneo (IT); Alessandro CHINI, Modena (IT)

(73) Assignee: STMICROELECTRONICS S.r.l., Agrate Brianza (IT)

(21) Appl. No.: 18/530,050

(22) Filed: Dec. 5, 2023

Related U.S. Application Data
(62) Division of application No. 17/396,154, filed on Aug. 6, 2021, now Pat. No. 11,862,707.
Application No. 17/396,154 is a continuation of application No. 16/690,035, filed on Nov. 20, 2019, now Pat. No. 11,101,363.
Application No. 16/690,035 is a division of application No. 15/159,045, filed on May 19, 2016, now Pat. No. 10,522,646.

(30) Foreign Application Priority Data
Nov. 12, 2015 (IT) 102015000072111

(51) Int. Cl. H01L 29/66; H01L 29/20; H01L 29/205; H01L 29/423; H01L 29/778

(52) U.S. Cl. CPC H01L 29/66462; H01L 29/205; H01L 29/4236; H01L 29/42376; H01L 29/7786; H01L 29/7787; H01L 29/2003

(57) ABSTRACT

A method forms an HEMT transistor of the normally off type, including: a semiconductor heterostructure, which comprises at least one first layer and one second layer, the second layer being set on top of the first layer; a trench, which extends through the second layer and a portion of the first layer; a gate region of conductive material, which extends in the trench; and a dielectric region, which extends in the trench, coats the gate region, and contacts the semiconductor heterostructure. A part of the trench is delimited laterally by a lateral structure that forms at least one first step. The semiconductor heterostructure forms a first edge and a second edge of the first step, the first edge being formed by the first layer.

### BACKGROUND

### Technical Field

The present disclosure relates to a high-electron-mobility transistor (HEMT) of the normally off type including a trench, which comprises a gate region and forms at least one step; further, the present disclosure regards the corresponding manufacturing method.

### Description of the Related Art

As is known, HEMT transistors, which are also known as “heterostructure field-effect transistors” (HFETs), are encountering wide diffusion, since they are characterized by the possibility of operating at high frequencies, as well as on account of their high breakdown voltages.

For instance, HEMT transistors are known that include AlGaN/GaN heterostructures, which, however, are devices of a normally on type, i.e., such that, in the absence of voltage on the respective gate terminals, there in any case occurs passage of current; equivalently, these transistors are said to operate in depletion mode. Since it is generally preferable to provide transistors of the normally off type (equivalently, operating in enrichment mode), numerous variants have been proposed, such as for example the transistor described in U.S. Pat. No. 8,587,031.

In detail, U.S. Pat. No. 8,587,031 describes a transistor including a heterostructure of a layer of aluminum gallium nitride (AlGaN) and by a layer of gallium nitride (GaN), arranged in contact with one another. Further, the transistor has a first gate region, which is arranged within a recess that extends in the AlGaN layer and enables modulation of a channel of the normally off type.

Today, there are thus available HEMT transistors operating in enrichment mode. However, these solutions are in any case affected by the so-called phenomenon of drain-induced barrier lowering (DIBL), also known as “early-breakdown phenomenon”. Unlike breakdown, the DIBL phenomenon occurs for low drain-to-source voltages (typically, for voltages comprised between 10 V and 30 V) and entails, in the presence of a zero voltage between gate and source, a sudden increase of the current that circulates between the drain and the source. In greater detail, denoting the voltages present between i) the gate and the source and between ii) the drain and the source as the voltages V_{gs} and V_{ds}, respectively, and the current that circulates between the drain and the source when V_{gs}=0 as the leakage current, when V_{ds}<V_{dibl} (where V_{dibl} is the voltage at which the DIBL phenomenon occurs) the leakage current density is typically of the order of nanoamps per millimeter. Instead, if V_{gs}=0 and V_{ds} exceeds V_{dibl}, the leakage current density may even be of the order of the microamps per millimeter. Since the DIBL phenomenon causes premature turning-on of the transistor, there is felt the need to prevent onset of this phenomenon, or in any case reduce the effects thereof.

### BRIEF SUMMARY

At least some embodiments of the present disclosure provide a HEMT transistor that will overcome at least in part the drawbacks of the known art.

According to the present disclosure a HEMT transistor includes:
a semiconductor heterostructure including a first semiconductor layer and a second semiconductor layer, the second semiconductor layer being arranged on top of the first layer;
a trench which extends through the second semiconductor layer and a portion of the first semiconductor layer;
a gate region of conductive material, which extends in the trench; and
a dielectric region which extends in the trench, coats the gate region, and contacts the semiconductor Heterostructure.

A part of the trench is delimited laterally by a lateral structure that forms a first step and the semiconductor heterostructure forms a first edge and a second edge of said first step, the first edge being formed by the first semiconductor layer.

At least some embodiments of the present disclosure provide a method for manufacturing a HEMT transistor that includes:
in a semiconductor heterostructure that includes a first semiconductor layer and a second semiconductor layer arranged on top of the first semiconductor layer, forming a trench that extends through the second semiconductor layer and a portion of the first semiconductor layer;
forming a gate region of conductive material within the trench;
within the trench, forming a dielectric region that coats the gate region and contacts the semiconductor heterostructure; and
forming a lateral structure that delimits laterally a part of the trench and forms a first step; and wherein the semiconductor heterostructure forms a first edge and a second edge of said first step, the first edge being formed by the first semiconductor layer.

### BRIEF DESCRIPTION OF THE SEVERAL VIEWS OF THE DRAWINGS

For a better understanding of the present disclosure, preferred embodiments thereof are now described, purely by way of non-limiting example and with reference to the attached drawings, wherein:

FIG. 1 is a schematic illustration of a cross-section (not in scale) of a portion of the present HEMT transistor;

FIG. 2 is a schematic perspective view (not in scale) of a trench of the HEMT transistor shown in FIG. 1;

FIG. 3 is a schematic illustration of a cross-section (not in scale) of a portion of the HEMT transistor shown in FIG. 1;

FIG. 4 shows two examples of plots, as a function of the drain-to-source voltage, of the leakage current, for a HEMT transistor of a known type and the present HEMT transistor, respectively;

FIG. 5 shows two examples of plots of the electrical field versus the drain voltage, for a HEMT transistor of a known type and for the present HEMT transistor, respectively;

FIGS. 6-8 and 15 are schematic cross-sectional views (not in scale) of further embodiments of the present HEMT transistor;

FIGS. 9-14 are schematic cross-sectional views (not in scale) of the HEMT transistor illustrated in FIG. 1, during successive steps of a manufacturing method.

### DETAILED DESCRIPTION

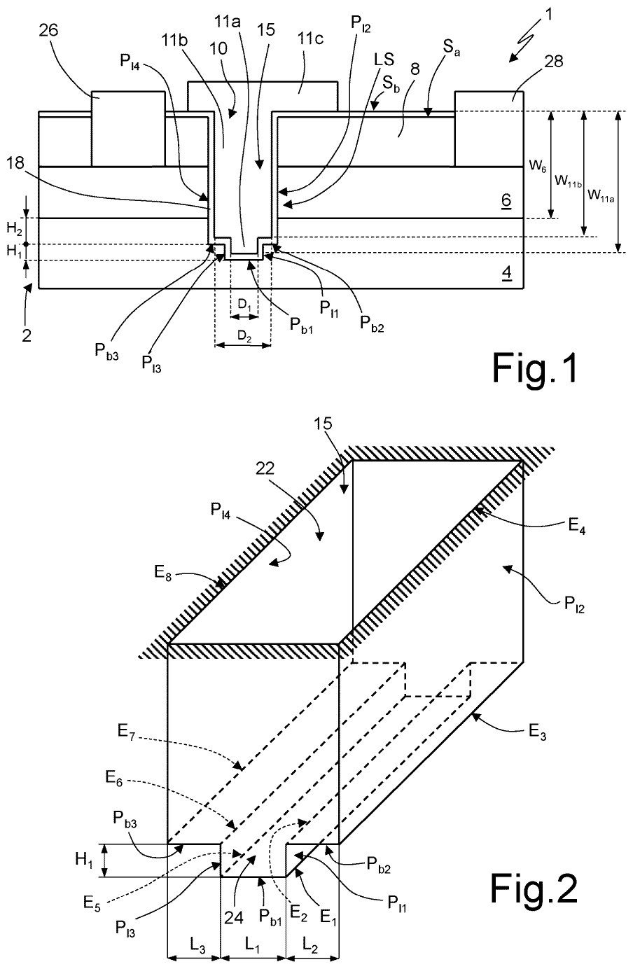

FIG. 1 shows a first embodiment of the present HEMT transistor, designated by 1.

In detail, the HEMT transistor 1 comprises a semiconductor body 2, which in turn comprises a first layer 4 and a second layer 6, referred to hereinafter as the bottom layer 4 and the top layer 6, respectively.

The bottom layer 4 is of a first semiconductor material, such as for example a first semiconductor alloy of elements of Groups III and V of the Periodic Table; purely by way of example, in what follows it is assumed that the bottom layer 4 is of gallium nitride (GaN).

The top layer 6 overlies the bottom layer 4, with which it is in direct contact, and is of a second semiconductor material, such as for example a second semiconductor alloy of elements of Groups III-V of the Periodic Table, this second semiconductor alloy being different from the first semiconductor alloy. Purely by way of example, in what follows it is assumed that the top layer 6 is of aluminum gallium nitride (AlGaN).

The bottom layer 4 and the top layer 6 are, for example, of an N type. Furthermore, the bottom layer 4 has a thickness of, for example, between 20 nm and 7 μm, while the top layer 6 has a thickness of, for example, between 5 nm and 400 nm.

Although not shown, the semiconductor body 2 further comprises a substrate, made for example of silicon, on which the bottom layer 4 is formed. Since this substrate is irrelevant for the purposes of the present disclosure, it will not be mentioned any further in the present description.

The HEMT transistor 1 further comprises a passivation region 8, which overlies, in direct contact, the top layer 6 and is made, for example, of silicon nitride. For instance, the passivation region 8 has a thickness of 100 nm. The passivation region 8 forms a first surface Sₐ of the HEMT transistor 1.

The HEMT transistor 1 further comprises a gate region 10, which extends inside a trench 15 and is of conductive material; for example, the gate region 10 may be made up of one or more metal layers, made for example of aluminum, nickel, or tungsten.

In detail, the trench 15 extends through the passivation region 8, starting from the first surface Sₐ, as well as through the top layer 6. Furthermore, the trench 15 traverses a top portion of the bottom layer 4, arranged in contact with the top layer 6.

In greater detail, the trench 15 is delimited by a first side wall Pₗ₁, a second side wall Pₗ₂, a third side wall Pₗ₃, and a fourth side wall Pₗ₄, which are mutually parallel and are perpendicular to the first surface Sₐ. Further, the trench 15 is delimited by a first bottom wall P_{b1}, a second bottom wall P_{b2}, and a third bottom wall P_{b3}, which are parallel to one another and to the first surface Sₐ.

In particular, the first bottom wall P_{b1} extends in the bottom layer 4, to a first depth (measured, for example, with respect to the first surface Sₐ). Also the second bottom wall P_{b2} and the third bottom wall P_{b3} extend in the bottom layer 4, to the same depth, which is less than the aforementioned first depth. Furthermore, the first side wall Pₗ₁ connects the first and second bottom walls P_{b1}, P_{b2}; the third side wall Pₗ₃ connects, instead, the first and third bottom walls P_{b1}, P_{b3}. Furthermore, the second side wall Pₗ₂ connects the second bottom wall P_{b2} to the first surface Sₐ; the fourth side wall Pₗ₄ connects the third bottom wall P_{b3} to the first surface Sₐ.

In practice, as shown in greater detail in FIG. 2, the first bottom wall P_{b1} and the first side wall Pₗ₁ form a first edge E₁; further, the first side wall Pₗ₁ and the second bottom wall P_{b2} form a second edge E₂, which is parallel to the first edge E₁, with which it is coplanar. In addition, the second bottom wall P_{b2} and the second side wall Pₗ₂ form a third edge E₃, which is parallel to the second edge E₂, with which it is coplanar. In turn, the second side wall Pₗ₂ forms a fourth edge E₄ with the first surface Sₐ (not shown in FIG. 2).

In addition, the first bottom wall P_{b1} and the third side wall Pₗ₃ form a fifth edge E₅; further, the third side wall Pₗ₃ and the third bottom wall P_{b3} form a sixth edge E₆, which is parallel to the fifth edge E₅, with which it is coplanar. In addition, the third bottom wall P_{b3} and the fourth side wall Pₗ₄ form a seventh edge E₇, which is parallel to the sixth edge E₆, with which it is coplanar. In turn, the fourth side wall Pₗ₄ forms an eighth edge E₈ with the first surface Sₐ.

In even greater detail, the first and third side walls Pₗ₁, Pₗ₃ are set apart from one another by a distance equal to L₁ (measured in a direction perpendicular to the first and third side walls Pₗ₁, Pₗ₃), which thus represents the width of the first bottom wall P_{b1}. The widths of the second and third bottom walls P_{b2}, P_{b3} are instead designated, respectively, by L₂ and L₃. In addition, the first and third side walls Pₗ₁, Pₗ₃ have a height equal to H₁, measured in a direction perpendicular to the first bottom wall Pₗ₁. Furthermore, as shown in FIG. 1, each one of the second and fourth side walls Pₗ₂, Pₗ₄ has a respective bottom portion, which extends starting, respectively, from the third and seventh edges E₃, E₇ until it contacts the top layer 6, this portion having a height H₂.

In practice, the trench 15 forms a first cavity 22 and a second cavity 24, communicating with one another and having the same length. The first cavity 22 gives out onto the first surface Sₐ, overlies the second cavity 24 and has a width equal to L₁+L₂+L₃; the second cavity 24 has a width equal to L₁. Purely by way of example, each of the widths L₁, L₂ and L₃ may be comprised between 0.1 μm and 10 μm; further, the height H₁ may, for example, be comprised between 1 nm and 500 nm, whereas the height H₂ may, for example, be comprised between 0 and 500 nm.

In other words, the first side wall Pₗ₁ and the second bottom wall P_{b2} form a first step, i.e., a first shoulder, of a lateral structure LS that delimits the trench 15 laterally and extends from a side of the first bottom surface P_{b1}. In particular, denoting the ensemble of the semiconductor body 2 and of the passivation region 8 as the main body, the lateral structure LS is formed by the main body. Furthermore, the second bottom wall P_{b2}, the second side wall Pₗ₂, and the first surface Sₐ form a sort of second step of the aforementioned lateral structure LS. The first and second steps are arranged in succession, in such a way that the lateral structure LS assumes a staircase profile. The HEMT transistor 1 further comprises a dielectric region 18, which is formed, for example, by aluminum nitride (AlN), or silicon nitride (SiN), or silicon oxide (SiO₂), and coats the first surface Sₐ. Furthermore, the dielectric region 18 internally coats the trench 15, i.e., coats, among others, the first, second, and third bottom walls P_{b1}, P_{b2}, P_{b3}, as well as the first, second, third, and fourth side walls Pₗ₁, Pₗ₂, Pₗ₃ and Pₗ₄. In this connection, as previously mentioned, the first, second, and third bottom walls P_{b1}, P_{b2}, P_{b3} are formed by the bottom layer 4, as also the first and third side walls Pₗ₁, Pₗ₃, while each of the second and fourth side walls Pₗ₂, Pₗ₄ is formed by the bottom layer 4, the top layer 6, and the passivation region 8.

In greater detail, the gate region 10 comprises a bottom portion 11a, arranged within the second cavity 24, and a central portion 11b, arranged within the first cavity 22, on the bottom portion 11a, with which it is in direct contact. The dielectric region 18 surrounds the bottom portion 11a and the central portion 11b of the gate region 10, which are thus arranged in the trench 15 more internally than the dielectric region 18 and are coated by the latter. In particular, the dielectric region 18 insulates the bottom portion 11a and the central portion 11b of the gate region 10 from the semiconductor body 2, as well as from the passivation region 8.

In even greater detail, the bottom portion 11a and the central portion 11b of the gate region 10 are both parallelepipedal in shape and have a width D₁ and a width D₂, respectively, with D₁<L₁ and D₂>L₁. Furthermore, without any loss of generality, the bottom portion 11a extends to a depth W₁₁ₐ (measured starting from the first surface Sₐ), greater than the maximum depth to which the top layer 6 (designated by W₆) extends; the central portion 11b extends, instead, to a depth W_{11b}<W₁₁ₐ. Without any loss of generality, in the embodiment shown in FIG. 1 we have W₆<W_{11b}.

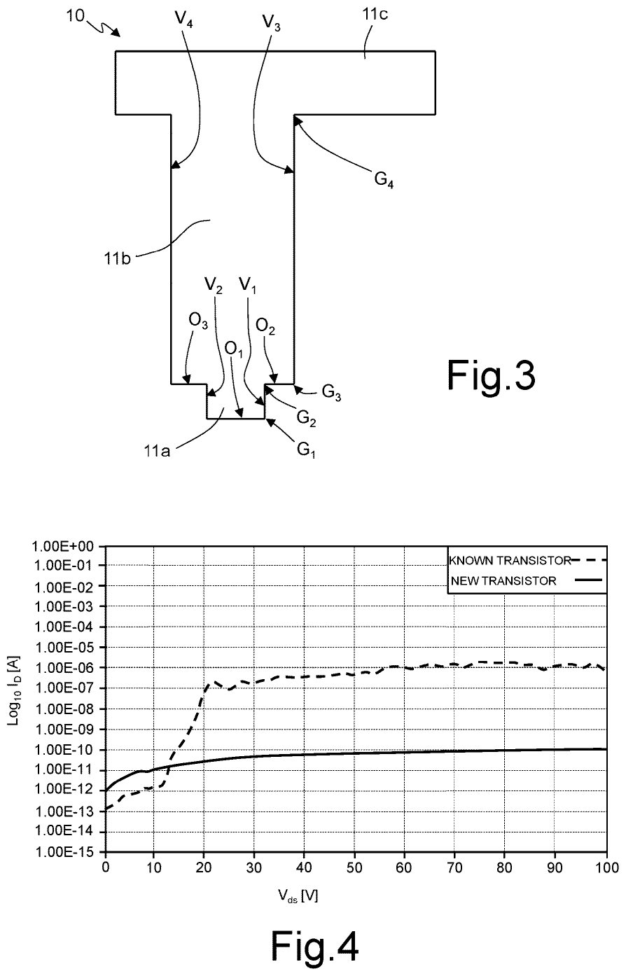

In other words, as shown in greater detail in FIG. 3, the gate region 10 is delimited at the bottom by a first horizontal wall O₁, a second horizontal wall O₂, and a third horizontal wall O₃ and by a first vertical wall V₁ and a second vertical wall V₂. In particular, the first horizontal wall O₁ delimits, at the bottom, the bottom portion 11a of the gate region 10, which is delimited laterally by the first and second vertical walls V₁, V₂. The central portion 11b of the gate region 10 is delimited, at the bottom (in part), by the second and third horizontal walls O₂, O₃. The first vertical wall V₁ connects the first and second horizontal walls O₁, O₂, with which it forms a corresponding step of the gate region 10. Likewise, the second vertical wall V₂ connects the first and third horizontal walls O₁, O₃, with which it forms a corresponding step of the gate region 10. Furthermore, the first horizontal wall O₁ and the first vertical wall V₁ form a first edge G₁ of the gate region 10, parallel to the first edge E₁ of the trench 15, while the first vertical wall V₁ and the second horizontal wall O₂ form a second edge G₂ of the gate region 10, parallel to the second edge E₂ of the trench 15.

As shown again in FIG. 3, the gate region 10 further comprises a top portion 11c, which extends on the central portion 11b, with which it is in direct contact. Furthermore, the central portion 11b of the gate region 10 is delimited laterally by a third vertical wall V₃ and a fourth vertical wall V₄, which are parallel to one another and face, respectively, the second and fourth side walls Pₗ₂, Pₗ₄ of the trench 15. The third vertical wall V₃ forms a third edge G₄and a fourth edge G₄of the gate region 10 with the second horizontal wall O₂ and the top portion 11c of the gate region 10, respectively.

In practice, to a first approximation, the dielectric region 18 has an approximately constant thickness inside the trench 15; i.e., it forms a sort of conformal layer that coats the walls of the trench 15; consequently, the part of gate region 10 contained within the trench 15 is delimited by a surface that follows the profile of the trench 15 (and thus of the lateral structure LS). Consequently, corresponding to each edge/step of the trench 15 is an edge/step of the part of gate region 10 contained within the trench 15.

Again with reference to FIG. 1, the portion of dielectric region 18 that extends on the first surface Sₐ is delimited at the top by a second surface S_{b}, substantially parallel to the first surface Sₐ. Furthermore, the top portion 11c of the gate region 10 has a width greater than L₁+L₂+L₃ and projects laterally both with respect to the second side wall Pₗ₂ and with respect to the fourth side wall Pₗ₄. Without any loss of generality, in the embodiment shown in FIG. 1, the top portion 11c of the gate region 10 projects laterally from the second side wall Pₗ₂ to a greater extent than the top portion 11c projects from the fourth side wall Pₗ₄.

The HEMT transistor 1 further comprises a source metallization 26 and a drain metallization 28, arranged on sides opposite to the trench 15 and to the top portion 11c of the gate region 10. Each one of the source metallization 26 and the drain metallization 28 traverses the portion of dielectric region 18 arranged on top of the front surface Sₐ and the portion underlying the passivation region 8 until it contacts the top layer 6. In a per se known manner, each one of the source metallization 26 and the drain metallization 28 may be formed, for example, by a corresponding plurality of metal layers (for example, of titanium, aluminum, and tungsten); further, a top portion of each one of the source metallization 26 and the drain metallization 28 extends up to a height greater than the height of the second surface S_{b}.

In greater detail, the second and fourth side walls Pₗ₂, Pₗ₄ of the trench 15 face the drain metallization 28 and the source metallization 26, respectively.

In use, the gate region 10, the dielectric region 18, and the bottom layer 4 form a MOSFET, the channel of which extends in the bottom layer 4, underneath the first bottom wall P_{b1}. This channel, of the normally off type, may be modulated by applying a voltage to the gate region 10.

In a per se known manner, underneath the interface between the bottom layer 4 and the top layer 6, thus in the bottom layer 4, a so-called “two-dimensional electron gas” (2DEG) is formed, which represents the channel (of the normally on type) of the HEMT transistor 1. Also this channel is modulated by the voltage present on the gate region 10, thanks to the presence, in the top portion 11c of the gate region 10, of a projection that extends, with respect to the underlying central portion 11b, towards the drain metallization 28, thus overlying a corresponding portion of the two-dimensional electron gas. In other words, the top layer 6 functions as barrier layer, whereas the bottom layer 4 functions as buffer layer.

The HEMT transistor 1 has thus, as a whole, a channel of the normally off type, thanks to the presence of the aforementioned MOSFET. Furthermore, it may be shown that the HEMT transistor 1 exhibits a leakage current of the type illustrated in FIG. 4, where there further appears an example of leakage current of a HEMT transistor of a known type.

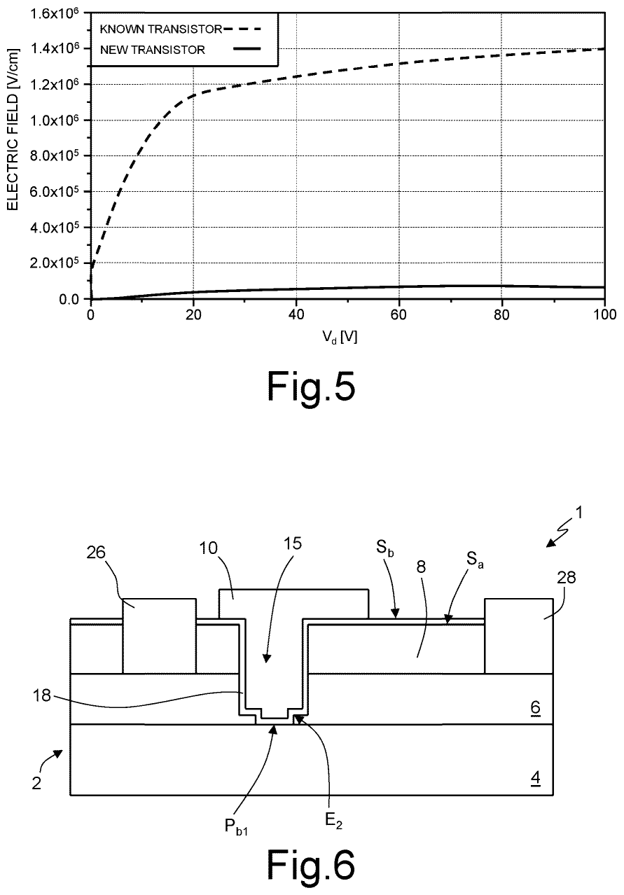

In practice, the HEMT transistor 1 is not affected by the DIBL phenomenon. This is due to the fact that, thanks to the presence of the aforementioned first step of the trench 15, the electrical field at the aforementioned first edge E₁ presents a pattern as a function of the drain voltage that is of the type shown in FIG. 5 (on the hypothesis of zero gate and source voltages), which further represents an example of the corresponding plot of the electrical field that arises in a HEMT transistor of a known type and where the gate region is formed in a recess of a traditional shape, at a bottom edge of this recess. In fact, the presence of the aforementioned first step of the lateral structure implies the presence, in the semiconductor body 2, of the third edge E₃; consequently, the electrical field is approximately shared between the first and third edges E₁, E₃.

Further possible are embodiments of the type shown in FIG. 1, but where the trench 15 extends to depths different from what has been described previously. For instance, as shown in FIG. 6, it is possible for the first bottom wall P_{b1} of the trench 15 to lie in the plane of the interface between the bottom layer 4 and the top layer 6. In this case, the gate region 10 is entirely on top of the bottom layer 4. Consequently, the second edge E₂ of the trench 15 and the aforementioned first step of the trench 15 are formed by the top layer 6. The first edge E₁ is instead still in contact with the bottom layer 4, and thus guarantees the aforementioned reduction of the electrical field.

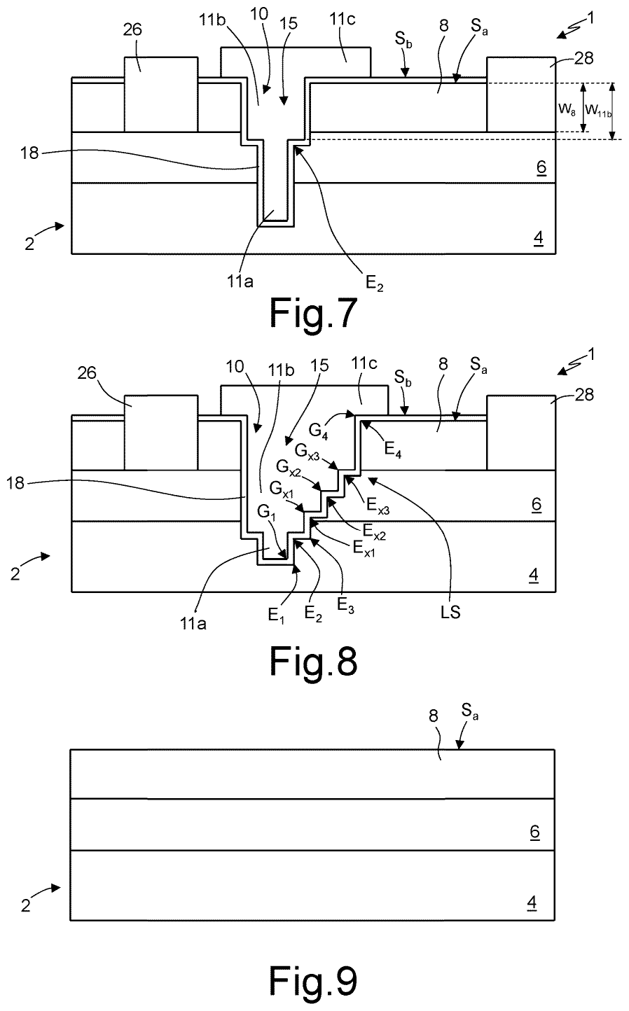

According to a different embodiment, shown in FIG. 7, the HEMT transistor 1 is of the same type as the one shown in FIG. 1, apart from the fact that the second edge E₂ of the trench 15 is formed by the top layer 6. Without any loss of generality, assuming that the passivation region 8 extends to a depth W₈, we have W_{11b}>W₈ even though variations where we have W_{11b}=W₈ are in any case possible.

In general, the embodiments shown in FIGS. 6 and 7 are characterized by low resistances between the source metallization 26 and drain metallization 28, since in both cases a part of the channel of the MOSFET is formed in the top layer 6; the consequent greater extension of the two-dimensional gas thus entails a reduction of the so-called R_{ON}.

FIG. 8 shows, instead, a further embodiment in which the lateral structure LS comprises more than two steps. For instance, without any loss of generality, in the embodiment shown in FIG. 8 the lateral structure LS forms, in addition to the aforementioned first and second steps (the upper edges of which E₂, E₄ are shown in FIG. 8), a further three steps, the upper edges of which are designated by Eₓ₁, Eₓ₂, and Eₓ₃, respectively. Purely by way of example, the edges Eₓ₁, Eₓ₂, and Eₓ₃ are formed by the top layer 6. The central portion 11 of the gate region 10 thus forms another three corresponding additional steps, the upper edges of which are designated by Gₓ₁, Gₓ₂ and Gₓ₃, respectively; without any loss of generality, in FIG. 8 the edge Gₓ₃ is set coplanar with the interface between the bottom layer 4 and the top layer 6.

It may be shown that, as the number of steps of the lateral structure LS increases, the electrical field present between the gate region 10 and the drain metallization 28 is distributed more evenly along the lateral structure LS since the corresponding peaks, located in the presence of the edges, reduce their own amplitude. In this way, any deterioration of the HEMT transistor during the turning off steps, in which the transistor is subjected to high drain voltages, is prevented.

The present HEMT transistor 1 may be produced, for example, by implementing the manufacturing method described in what follows. Without any loss of generality and purely by way of non-limiting example, the manufacturing method is described with reference to production of the HEMT transistor 1 shown in FIG. 1.

Initially, as shown in FIG. 9, the main body, including the semiconductor body 2 and the passivation region 8, is provided in a per se known manner.

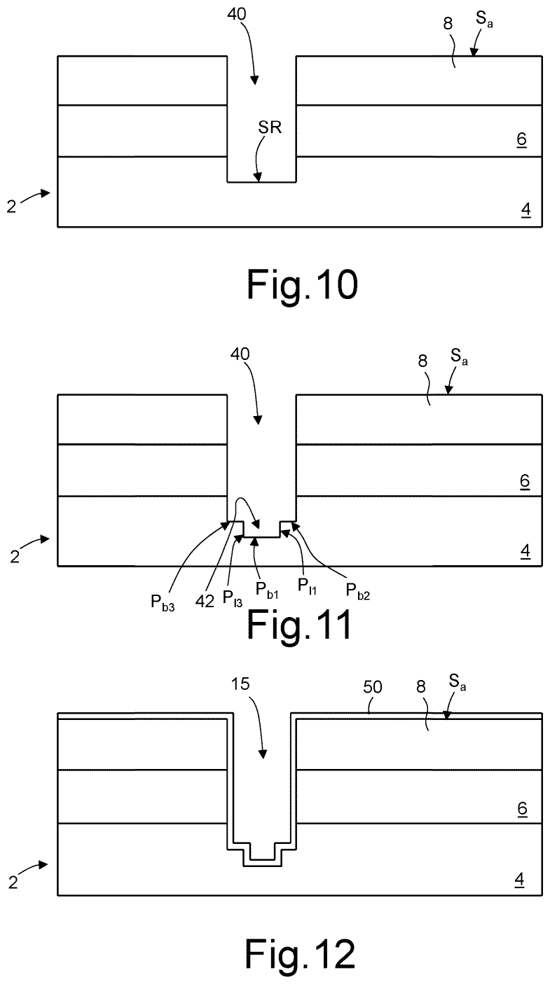

Next, as shown in FIG. 10, in a per se known manner, a photolithographic process and a subsequent etching process are carried out in order to remove selectively a portion of the passivation region 8, an underlying portion of the top layer 6, and an underlying portion of the bottom layer 4 for forming a first recess 40, which has the shape of a parallelepiped and has a depth greater than the aforementioned depth W_{11b}. The first recess 40 is delimited, at the bottom, by a plane surface SR, formed by the bottom layer 4, and is designed to house the central portion 11b of the gate region 10 and the portion of dielectric region 18 that coats it.

Next, as shown in FIG. 11, in a per se known manner a further photolithographic process and a subsequent further etching process are carried out in order to remove selectively a portion of the bottom layer 4, starting from the plane surface SR. In particular, a portion of the bottom layer 4 that forms a central portion of the plane surface SR is removed, said central portion separating a pair of lateral portions of the plane surface SR, which in turn form the second and third bottom walls P_{b2}, P_{b3}, respectively, of the trench 15. In this way, a second recess 42 is formed, which is delimited at the bottom by the first bottom wall P_{b1} and has a smaller width than the first recess 40. The second recess 42 is further delimited laterally by the first and third side walls Pₗ₁, Pₗ₃ and is designed to house the bottom portion 11a of the gate region 10, and thus extends to a depth greater than the aforementioned depth W₁₁ₐ. The first and second recesses 40, 42 form the trench 15.

Next, as shown in FIG. 12, formed on the first surface Sₐ and within the trench 15 is a dielectric layer 50, made, for example, of aluminum nitride or silicon nitride. The dielectric layer 50 thus coats the walls of the trench 15 and is formed, for example, by deposition.

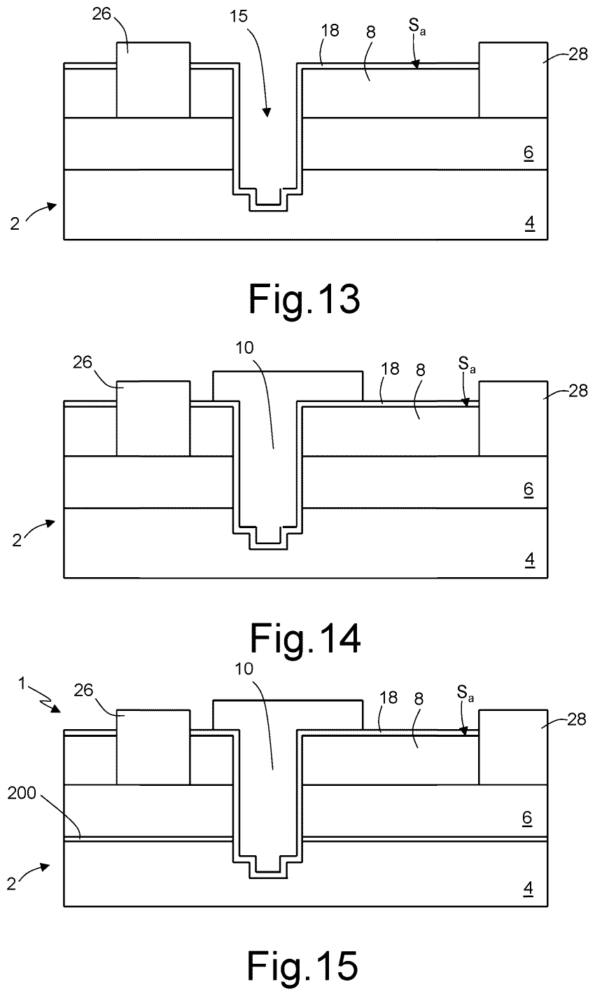

Next, as shown in FIG. 13, the source metallization 26 and the drain metallization 28 are formed in a per se known manner. For this purpose, even though not shown in detail, it is possible to carry out a further photolithographic process and a subsequent etching process for removing selectively portions of the dielectric layer 50 and underlying portions of the passivation region 8, to form cavities designed to house, respectively, the source metallization 26 and the drain metallization 28, which are subsequently formed within these cavities by the so-called “lift-off” technique. According to the lift-off technique, by photolithography a resist mask is formed, which leaves exposed just the regions of the HEMT transistor 1 that are to be overlaid by the source metallization 26 and by the drain metallization 28. Next, metal material is deposited on the HEMT transistor 1; subsequent removal of the resist mask also entails removal of the metal material overlying the resist mask itself. Once the source metallization 26 and the drain metallization 28 are formed, what remains of the dielectric layer 50 forms the dielectric region 18.

Next, even though not shown, a thermal process is carried out, for example at a temperature comprised between 500° C. and 900° C. for formation of the contacts.

Next, as shown in FIG. 14, the gate region 10 is formed, the bottom and central portions 11a, 11b of which extend within the trench 15. Also the gate region 10 may be formed by a corresponding lift-off process, which envisages forming a corresponding resist mask, depositing conductive material both on the mask and on the portion of HEMT transistor 1 left free from the mask, and subsequently removing the resist mask and the conductive material arranged on top of it.

As regards, instead, embodiments of the type shown in FIG. 8, i.e., embodiments in which the lateral structure LS forms more than two steps, they may be formed for example by carrying out the steps (not shown) of:
a) removing selectively a top portion of the main body for removing a corresponding recess, delimited by a bottom surface;
b) starting from the aforementioned bottom surface, removing selectively an underlying portion of main body for forming a further recess, delimited by a respective bottom surface, the further recess having a width smaller than the previous recess and being laterally staggered with respect to the side walls of the previous recess; and
c) iterating step b) until formation of the desired number of steps.

In the case where the manufacturing method just described above is adopted, the shape of the trench 15 may differ from what is shown in FIG. 8; in particular, the portion of trench 15 facing the source metallization 26 may include a number of steps equal to that of the lateral structure LS.

From what has been described and illustrated previously, the advantages that the present solution affords emerge clearly.

In particular, the present HEMT transistor is substantially immune from the DIBL phenomenon since, in use, the electrical field at the first edge E₁ (in contact with the first layer 4) is reduced, thanks to the presence in the semiconductor body 2 of at least the third edge E₃.

In conclusion, it is clear that modifications and variations may be made to what has been described and illustrated so far, without thereby departing from the scope of the present disclosure.

For instance, each one of the source metallization 26 and the drain metallization 28 may penetrate in part within the top layer 6, as well as possibly also in a top portion of the bottom layer 4.

The bottom layer 4 may include a respective top portion and a respective bottom portion (not shown), which are doped for example with carbon atoms; in this case, the top portion is doped with carbon atoms to an extent smaller than the bottom portion and functions as so-called channel layer, whereas the bottom portion of the bottom layer 4 functions as buffer layer. In this case, if the second and third bottom walls P_{b2}, P_{b3} are formed by the bottom layer 4, they may be formed indifferently by the top portion or by the bottom portion of the bottom layer 4.

Doping of the semiconductor body 2 may be of a type different from what has been described. For instance, the bottom layer 4 and the top layer 6 may be of a P type.

As regards the trench 15, the portion of trench 15 arranged between the first bottom wall P_{b1} and the source metallization 26 may have a shape different from what has been described. For instance, embodiments are possible of the type shown in FIG. 1 but where the third bottom wall P_{b3} is absent, in which case the third and fourth side walls Pₗ₃, Pₗ₄ are replaced by a single side wall. In this connection, it may be noted how, for the purposes of prevention of the DIBL phenomenon, the shape of the further lateral structure that delimits the trench 15 laterally and is opposite to the lateral structure LS is to a first approximation irrelevant since the electrical field between the source metallization 26 and the gate region 10 is less intense than the electrical field present between the gate region 10 and the drain metallization 28.

The passivation region 18 may be absent, in which case the first surface Sₐ is formed by the top layer 6.

Again, as shown in FIG. 15, between the bottom layer 4 and the top layer 6 there may be present a spacer layer 200, made, for example, of aluminum nitride and having a smaller thickness, for example of 1 nm; the spacer layer 200 has the purpose of improving the mobility of the two-dimensional electron gas. In general, there are thus possible further embodiments that correspond to embodiments described previously but further include the spacer layer 200. In these further embodiments, the spatial distribution of the steps and of the edges of the lateral structure LS may, for example, correspond to that of the corresponding embodiments described previously in the sense that, if in a previous embodiment an edge of a step is formed by a given layer (for example, the bottom layer 4 or the top layer 6), in the corresponding further embodiment the corresponding edge is again formed by that given layer.

Once again with reference to the lateral structure LS, even though previously orthogonal steps have been described, i.e., steps that connect pairs of horizontal surfaces by vertical surfaces, it is, however, possible for the vertical surfaces of one or more steps to be transverse with respect to the corresponding horizontal surfaces and/or for one or both of the horizontal surfaces of one or more steps to be replaced by surfaces that are not parallel to the first surface Sₐ. In other words, in general the walls and the vertical surfaces may be not perfectly orthogonal to the first surface Sₐ.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method for manufacturing normally off heterostructure field-effect transistor (HEMT), the method comprising:
depositing a passivation layer on a semiconductor heterostructure; and
forming, in the passivation layer and the semiconductor heterostructure, a trench including a planar vertical sidewall on a first side of the trench in the semiconductor heterostructure and a plurality steps laterally opposite the vertical sidewall on a second side of the trench in the semiconductor heterostructure.

2. The method of claim 1, further comprising:
coating the vertical sidewall and the plurality of steps with a dielectric layer; and
depositing a conductive gate region on the dielectric layer in the trench.

3. The method of claim 2, further comprising:
coating a top surface of the passivation layer with the dielectric layer; and
depositing the conductive gate region on the dielectric layer on the top surface of the passivation layer.

4. The method of claim 1, wherein the heterostructure includes a first semiconductor layer and a second semiconductor layer on the first semiconductor layer, wherein the vertical sidewall extends entirely through the second semiconductor layer.

5. The method of claim 4, wherein the plurality of steps are in the second semiconductor layer.

6. The method of claim 5, further comprising forming a source metalization extending through the passivation layer and contacting the second semiconductor layer.

7. The method of claim 4, further comprising forming the trench entirely through the second semiconductor layer and partially through the first semiconductor layer.

8. A method for manufacturing normally off heterostructure field-effect transistor (HEMT), the method comprising:
forming a semiconductor heterostructure including:
a first semiconductor layer; and
a second semiconductor layer on the first semiconductor layer;
forming a passivation layer of dielectric material on the semiconductor heterostructure;
forming a trench extending entirely through the passivation layer, entirely through the second semiconductor layer, and partially through the first semiconductor layer, the trench including:
a bottom surface;
a first step on a first side of the trench, the first step having a horizontal surface higher in the trench than the bottom surface;
a plurality of second steps on a second side of the trench each having a respective horizontal surface higher in the trench than the bottom surface;
forming a dielectric layer coating the first and second steps;
forming a conductive gate region on the dielectric layer and filling the trench; and
forming a source metallization extending through the passivation layer and in contact with the second semiconductor layer.

9. The method of claim 8, wherein the first and second semiconductor layers include, respectively, gallium nitride and aluminum gallium nitride.

10. The method of claim 8, wherein the first and second semiconductor layers are of two materials that are configured to generate a two-dimensional electron gas in the first semiconductor layer.

11. The method of claim 8, wherein the dielectric layer is on a top surface of the passivation layer, wherein the conductive gate region is on the dielectric layer on the top surface of the passivation layer.

12. The method of claim 8, wherein the plurality of second steps are in the second semiconductor layer.

13. The method of claim 8, wherein the first step is in the first semiconductor layer.

14. A method for manufacturing normally off heterostructure field-effect transistor (HEMT), the method comprising:
forming a semiconductor heterostructure including:
a first semiconductor layer of gallium nitride; and
a second semiconductor layer of aluminum gallium nitride;
forming a passivation layer of dielectric material on the semiconductor heterostructure;
forming a trench in the passivation layer and the semiconductor heterostructure, the trench including:
a bottom surface;
a planar vertical sidewall in the semiconductor heterostructure on a first side of the trench; and
a plurality of first steps each including a respective horizontal surface higher in the trench than the bottom surface and a respective vertical surface laterally opposite the planar vertical sidewall on a second side of the trench in the semiconductor heterostructure, wherein the planar vertical sidewall extends entirely through the second semiconductor layer.

15. The method of claim 14, further comprising:
forming a dielectric layer on the planar vertical sidewall and the plurality of first steps; and
forming a conductive gate region on the dielectric layer in the trench.

16. The method of claim 15, wherein the dielectric layer is on a top surface of the passivation layer, wherein the conductive gate region is on the dielectric layer on the top surface of the passivation layer.

17. The method of claim 14, wherein the plurality of first steps are in the second semiconductor layer.

18. The method of claim 14, wherein the planar vertical sidewall extends partially into the first semiconductor layer.

19. The method of claim 14, wherein the first and second semiconductor layers are of two materials that are configured to generate a two-dimensional electron gas in the first semiconductor layer.

20. The method of claim 14, further comprising forming a source metallization extending through the passivation layer and contacting the second semiconductor layer.
